(19) United States
(12) Patent Application Publication
(10) Pub. No.: US 2020/0174506 A1
(43) Pub. Date: Jun. 4, 2020

(54) System and method for controlling temperature

(71) Applicants: Benigno Rafael Elejalde, Milwaukee, WI (US); Andres Elejalde, Milwaukee, WI (US)

(72) Inventors: Benigno Rafael Elejalde, Milwaukee, WI (US); Andres Elejalde, Milwaukee, WI (US)

(21) Appl. No.: 16/208,456

(22) Filed: Dec. 3, 2018

(51) Int. Cl. G05D 23/20; G01K 15/00; G01R 35/00; G05D 23/13; G05D 23/19

(52) U.S. Cl. CPC G05D 23/20; G01K 15/005; G05D 23/1919; G05D 23/1326; G01R 35/005

(57) ABSTRACT

An iterative computer-implemented method and laboratory apparatus for calibrating and controlling the temperature: at a user device, remote from the apparatus: receiving a series of programming inputs from a user at a programming interface application on the user device; receiving a set of sensor measurements from the apparatus; automatically generating a set of control instructions for the apparatus based on a programming input of the series and the set of sensor measurements; and sending the set of control instructions to the apparatus; at the apparatus: receiving the set of control instructions from the user device; operating the apparatus based on the set of control instructions; recording a second set of sensor measurements during the apparatus operation; and sending the second set of sensor measurements to the user device; to the user device.

### CROSS-REFERENCE TO RELATED APPLICATIONS

None.

### TECHNICAL FIELD

This invention relates generally to the laboratory device field, and more specifically to a new and useful system and method for calibrating and controlling the temperature of an apparatus in the laboratory device field.

### BACKGROUND

There continues to be an emphasis in the laboratory device field to calibrate and control the ambient environment of samples. However, current laboratory devices do not allow users to calibrate and control the temperature within said devices. Thus, there is a need in the laboratory device field to create a new and useful system and method for calibrating and controlling the temperature of a laboratory apparatus.

### BRIEF DESCRIPTION OF THE FIGURES

FIG. 1A is schematic representation of a variation of the system.

FIG. 1B is a schematic representation of a variation of the apparatus.

FIG. 2A is a flowchart representation of a variation of the method, as performed by the apparatus.

FIG. 2B is a flowchart representation of a variation of the method, as performed by the user device.

FIG. 3 is a schematic representation of a variation of the method, as performed by the system.

FIG. 4 is an example schematic representation of the system operating in a variation of the visual programming mode.

FIG. 5 is a schematic representation of a variation of the method, including executing a set of programming inputs.

FIG. 6 is a schematic representation of a variation of the method, including operating the apparatus based on the user profile.

FIG. 7 is a schematic representation of a user device-to-apparatus topology variation.

### DETAILED DESCRIPTION OF THE EMBODIMENTS OF THE INVENTION

The following description of preferred embodiments of the invention is not intended to limit the invention to these preferred embodiments, but rather to enable any person skilled in the art to make and use this invention.

### 1. System for Calibrating and Controlling the Temperature within a Laboratory Apparatus

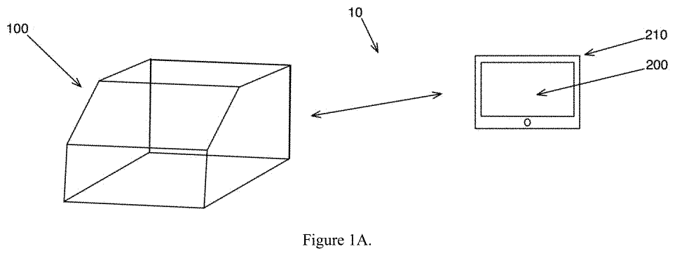

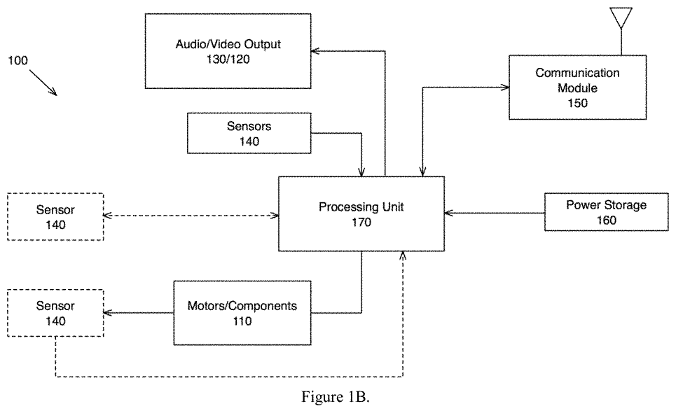

As shown in FIG. 1A, a system 10 for calibrating and controlling the temperature within a laboratory apparatus can include an apparatus 100 and at least one programming interface application 200. In particular, the system can include a distinct physical laboratory apparatus in wireless or wired communication with an application operable on a user device 210. The system functions to control the temperature within the apparatus. The system preferably leverages partial operational dependence between the apparatus and the programming interface application, but can alternatively allow the apparatus to operate entirely independently, or enable any other suitable method of apparatus control.

### 1.1 Laboratory Apparatus

As shown in FIG. 1B, the apparatus 100 preferably includes a set of outputs, a set of sensors, and a communications module. The apparatus functions as a programmable device, and can interact with its environment independent of the programming interface application, offload processing and operational decisions to the programming interface application when the apparatus and programming interface application are in communication, or operate in any other suitable manner.

The apparatus 100 is preferably capable of interacting with an environment. The apparatus can have any suitable form factor, but is preferably structured to feature an internal cavity capable of storing a laboratory specimen shown in FIG. 1A. However, any suitable form of the apparatus can be used. The apparatus preferable includes components configured to support operation of a laboratory apparatus such as a power system, a processing unit, storage, and other suitable elements.

The output of the apparatus functions to interact with the physical environment surrounding the apparatus, with one or more users, with other apparatuses, or with any other suitable endpoint. The outputs can include visual outputs 120, audio output 130, or any other suitable output. The outputs are preferably arranged on the apparatus, but can alternatively be remote outputs controlled by the apparatus, or be arranged in any other suitable location.

The visual outputs 120 can include controllable lighting system(s), a graphical display, a tabular display, or any other suitable visual display. The audio output 130 can include speakers, transducers, or any other suitable mechanism capable of generating audio waves. However, the apparatus can include any other suitable output.

The input of the apparatus functions to receive user inputs at the apparatus, receive inputs from other apparatuses, receive inputs from auxiliary sensors remote from the apparatus, measure parameters of the ambient environment, measure apparatus operational parameters, or provide any other suitable information. The apparatus can respond to the inputs according to the programming The apparatus can additionally or alternatively stream the input information to a remote user device, wherein the remote user device can process, store, or otherwise handle the input information.

The inputs can be one or more sensors 140, but can alternatively or additionally be interfaces for communicatively coupling with one or more sensors (e.g., connectors, etc.). Sensor inputs can include light sensors, wind sensors, radiation sensors, pressure sensors, temperature sensors, humidity sensors, touch sensors (e.g., a set of electrodes, etc.), user inputs (e.g., buttons, analog controls, digital controls, etc.), and/or any suitable type of input. The sensors can additionally include system monitoring sensors that function to monitor apparatus operational parameters, ambient environment parameters, or any other suitable parameters. Examples of monitoring sensors include motor monitoring systems (e.g., rotary encoders, mechanical encoders, magnetic encoders, optical encoders, resolvers, Hall effect sensors, back EMF monitoring systems, etc.), light sensors, audio sensors (e.g., microphones), temperature sensors, and pressure sensors, but the apparatus can include any other suitable sensor.

The communication module 150 of the apparatus functions to transfer information between the apparatus and a data endpoint. The data endpoint can be the programming interface application, a user device, server system, or be any other suitable device. The communication module 150 is preferably a transceiver, but can alternatively be a receiver, transmitter, or be any other suitable communication system. The communication module 150 can be wired or wireless. The communication module 150 can an IR system, RF system, beacon system (e.g., ultrasound, RF), light modulation system, NFC system, Wi-Fi system, GSM system, Bluetooth system, mesh system, cellular system, Ethernet system, powerline communication system, or be any other suitable communication system.

The apparatus 100 can additionally include a power storage unit 160 that functions to store energy and supply power to active apparatus components. The power storage unit is preferably arranged on-board the apparatus, but can alternatively be remote. The power storage unit 160 can be a primary battery, secondary batter (rechargeable battery), fuel cell, or be any other suitable power supply.

The apparatus 100 can additionally include a processing unit 170 that functions to control the apparatus output, communication system, or other components. The processing unit 170 can independently and/or automatically control the apparatus based on sensor measurements and stored control instructions. The processing unit 170 can additionally or alternatively operate the apparatus based on control instructions received from the programming interface application 200, user device 210, or other remote control system. The processing unit 170 can additionally or alternatively adjust or otherwise modify the received control instructions (e.g., based on stored user profile, sensor measurements, etc.). The processing unit 170 can be a processor, microprocessor, GPU, CPU, or be any other suitable processing unit. The processing unit can additionally include digital memory (e.g., flash memory, RAM, solid state, etc.) that functions to permanently or temporarily store information. The stored information can be control instructions (e.g., a user profile), sensor measurements or other input, identifier information (e.g., apparatus identifier information, user identifying information, user device identifier information, etc.), or be any other suitable information. The processing unit can include a local control system that functions to control the apparatus independent of the programming interface application, and can additionally include a remote control system that functions to control the apparatus based on control instructions received from the remote control device. The remote control system is preferably accessed through a programming interface application, but can alternatively be accessed through a remote cloud computing system or accessed in any other suitable manner. The local control system can store inputs, process programming configuration, direct output control, and provide any suitable form of control. In some variants, the local control system can be configured with a user profile configuration.

A user profile configuration of an embodiment of the apparatus functions to supply operational pattern directives. The user profile configuration preferably characterizes the type of actions and control instructions that is executed by the apparatus. The user profile configuration can define output responses to inputs. For example, the user profile configuration can specify that the apparatus should initialize lighting when it detects motion, initialize an alarm when a component malfunction is detected, notify the user at the completion of a set of programming instructions, or perform any suitable logic. The user profile configuration is preferably updatable, and preferably evolves or otherwise updates according to interactions and programming received from the programming interface application. The user profile configuration preferably initializes in a new instance of an apparatus as a base user profile. In one preferred implementation, base user profile defines default or minimal response logic, which functions to simulate a new apparatus. The user profile configuration preferably updates through apparatus and/or application interactions. Over time, the user profile configuration updates to provide customized response logic at least partially set through interactions of a user. At least a portion of the user profile configuration is stored and maintained on the apparatus such that the apparatus can conform to user profile-based behaviors independent of the application (e.g., when the apparatus is disconnected from or not controlled by a user device). The user profile configuration can additionally or alternatively be stored and managed remotely (e.g., by the application or in a remote cloud platform).

In a specific variation, the apparatus 100 includes a set of opposing motorized mounting points configured to removably connect to a set of accessories and/or rotate about a shared rotational axis; a set of visual output mechanisms (e.g., individually indexed and controllable light emitting elements); a set of audio output mechanisms (e.g., speakers); a set of light sensors; a set of audio sensors; a motor monitoring system for each or a subset of the apparatus motors; a set of buttons; a wireless communication mechanism (e.g., a Bluetooth communication mechanism). The apparatus can additionally include a processor, non-volatile memory, on-board power storage (e.g., a secondary or rechargeable battery) electrically connected to the active apparatus components, and/or include any other suitable component. However, the apparatus can have any other suitable component or configuration.

### 1.2 Programming Interface Application

The programming interface application 200 functions to provide a programming and interaction control interface to the apparatus. The programming interface application 200 functions to receive programming inputs from a user, and can additionally or alternatively transform the programming input into a second computer language (e.g., target language, such as assembly language or machine code). The programming interface application 200 can additionally or alternatively provide audio and/or visual feedback to the user.

The programming interface application 200 preferably runs on (e.g., is supported by) a user device 210, but can alternatively be run on a remote server or on any other suitable computing system. The user device is preferably remote from the apparatus (e.g., separate and distinct from the apparatus, not physically connected to the apparatus, etc.), but can alternatively be connected to the apparatus, mounted to the apparatus, or otherwise associated with the apparatus. The user device can be any suitable computing device, such as a mobile device (e.g., smartphone, tablet, etc.), wearable computer, a desktop computer, a TV-connected computer, a mobile phone, another electronic apparatus, or any suitable computing device. The system can include one or more programming interface applications that can interact with the apparatus.

The programming interface application 200 preferably includes a user interface configured to promote programming and setting of apparatus logic. Various approaches to programming can be applied as described such as visual programming and direct programming When in communication with the apparatus, the programming interface application preferably provides a substantial portion of control instructions. Input data captured by the apparatus can be communicated to the programming interface application (e.g., in near-real time, at a predetermined frequency, at a variable frequency, at a fixed frequency, etc.), where the input data is processed and transformed into response data, which is then communicated to the apparatus to be executed. Alternatively, the control instructions can have any suitable distribution between the apparatus and the programming interface application. The use of the programming interface application preferably facilitates updating and modification of the user profile instance of an apparatus.

The programming interface application 200 preferably uses an apparatus application programming interface or a software development kit, which functions to facilitate interfacing with the apparatus. Any suitable programmatic interface can be used. The interface is preferably generalized for use with various applications and uses. Preferably, there are multiple programming interface applications that can be selectively (or simultaneously) in control of the apparatus.

The programming interface application 200 can additionally supplement the components of the apparatus. For example, the programming interface application can be used to supply audio output. The programming interface application can similarly use sensors of the computing device to supplement or replace the inputs of the apparatus.

The system can additionally include a remote cloud platform that can facilitate account management, user profile synchronization, and other suitable features.

### 2. Method for Calibrating and Controlling the Temperature within a Laboratory Apparatus

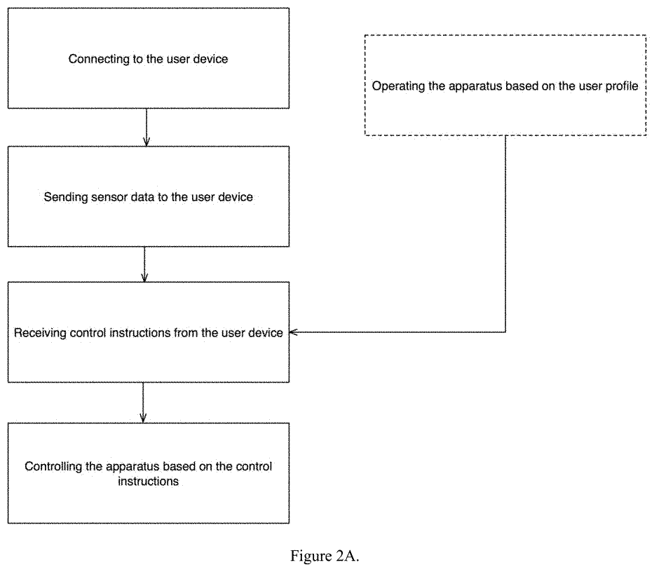

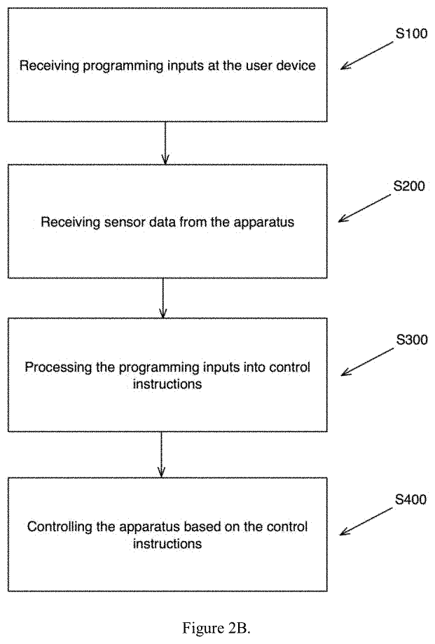

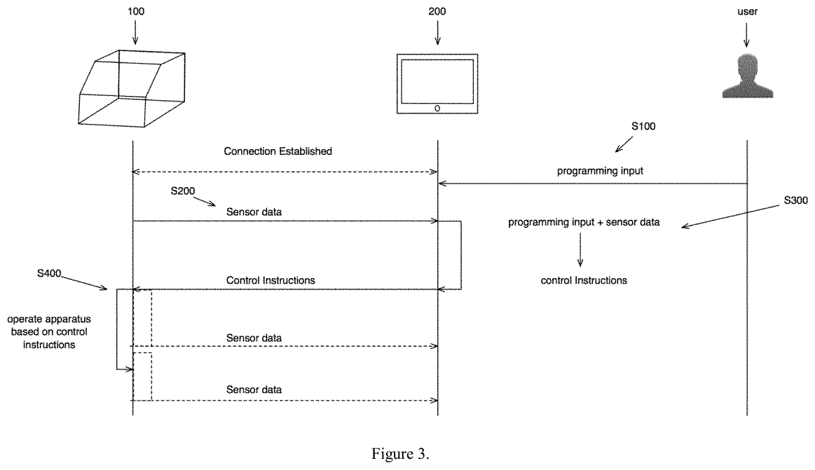

As shown in FIG. 2B and FIG. 3, a method for calibrating and controlling the temperature within a laboratory apparatus includes: receiving programming inputs at the user device S100; receiving sensor data from the apparatus at the user device S200; processing the programming inputs, based on the sensor data, into control instructions S300; and controlling the apparatus based on the control instructions S400. The method can additionally include controlling an apparatus according to a control user profile S500, receiving programming input, and updating the user profile based in part on the programming input.

The method can additionally function to enable a user to program the apparatus in real- or near-real time. The method preferably uses an apparatus that obtains environmental information and then responds through actions. Apparatus control can be partially or entirely directed through programming obtained from an application.

In one variation of apparatus operation, the apparatus can stream sensor information (recorded by the apparatus, such as sensor measurements) to the programming interface application (supported by a remote user device), wherein the user device can generate control instructions for the apparatus based on the sensor information. The user device can stream the control instructions to the apparatus, wherein the apparatus operates based on the control instructions, such that the user device can remotely control the apparatus. The apparatus can stream the sensor information in real- or near-real time (e.g., as the measurements are recorded), in batches, at a predetermined frequency, in response to a transmission event (e.g., the full execution of a control instruction), or at any other suitable frequency. In a second variation of apparatus operation, the apparatus can automatically operate based on a user profile configuration or other stored control information. However, the apparatus can operate in any other suitable manner.

### 2.1 Receiving Programming Inputs at the User Device

Receiving a set of programming inputs at the user device S100 functions to obtain a programming configuration from a user. The programming inputs can be programming components, programming routines, scripts, application logic, compiled application objects, or any suitable configuration that can direct control instructions of an apparatus. The set of programming inputs can include one or more programming inputs, and can define a control path. When the set includes multiple programming inputs, the set can be time-ordered (e.g., be a series or sequence of programming inputs), be unordered, or have any other suitable relationship between programming inputs of the set. The programming inputs are preferably programming statements expressing apparatus actions to be carried out, but can additionally or alternatively be simple statements, compound statements, or be any other suitable programming statements. However, the programming inputs can be expressions or be any other suitable programming input.

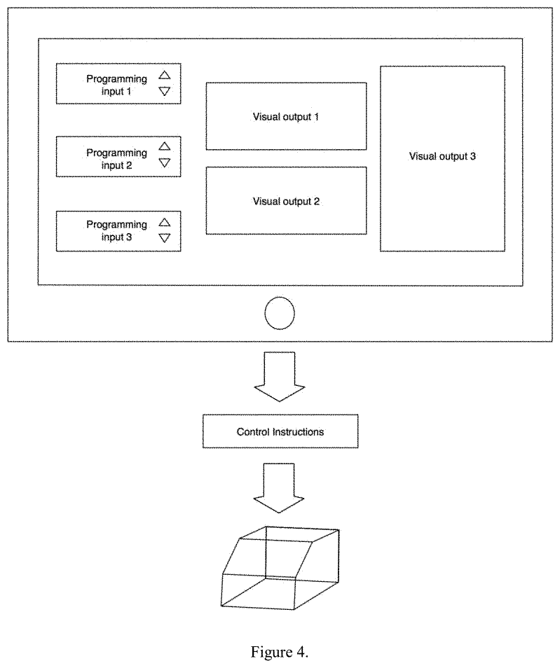

The set of programming inputs is preferably received through a programming interface application running on a user device (example shown in FIG. 4) S130. The visual programming mode can use any suitable visual programming mechanic. However, the programming inputs can be received in any other suitable manner. The programming interface application can be an application website, physical controller, or other suitable interface through which programmed behavior can be specified. The user device can be remote from the apparatus, physically connected to the apparatus (e.g., by a wire), mounted to the apparatus, or be otherwise associated with the apparatus. The programming inputs are preferably received from a user, but can alternatively be received from a second apparatus, a remote computing system (e.g., a server), or from any other suitable source. The programming inputs can be received before, during, or after apparatus connection with the user device; before, during, or after apparatus execution of the programming inputs; or be received at any other suitable time. The programming inputs can represent apparatus operation, apparatus audio output, apparatus visual output, a conditional statement, or represent any other suitable apparatus functionality (apparatus capability) or programming statement.

The set of programming inputs can be received in a variety of different ways, through a variety of different programming interface applications, wherein each programming interface applications is capable of interfacing with the apparatus. Alternatively, the programming input can be received through a single programming interface application, received thorough a set of different programming interface modes, or received in any other suitable manner. The apparatus interface, more preferably an apparatus software application interface but alternatively any other suitable apparatus interface, can additionally or alternatively provide a variety of programming input modes, each capable of interfacing with one or more programming interface applications, but the programming input modes can alternatively be natively enabled within an application. The various programming input modes can be used separately or in any suitable combination.

### 2.2 Receiving Sensor Data from the Apparatus at the User Device

Receiving sensor data from the apparatus at the user device S200 functions to receive feedback of apparatus control instruction performance, receive apparatus inputs for further control instruction generation (e.g., for continued remote apparatus control), receive data for apparatus performance analysis, receive data for control path determination, or receive data for any other suitable functionality. Receiving sensor data can include: sending sensor data from the apparatus to the user device, and receiving the sensor data from the apparatus at the user device. The sensor data can be sent by the apparatus at a predetermined frequency (e.g., a fixed or variable frequency), sent in response to the occurrence of a transmission event (e.g., in response to depression of an apparatus button, in response to receipt of a transmission command from the user device, etc.), sent as the sensor data is generated or recorded (e.g., in real- or near-real time), sent in response to apparatus connection with the user device, or be sent at any other suitable time. The apparatus can additionally compress, encrypt, or otherwise process the sensor data before transmission. The sensor data can be raw sensor data (e.g., raw sensor signals), processed measurements (e.g., wherein the signals are processed into sensor measurements), sensor summaries (e.g., wherein the measurements can be processed into higher-level summaries), or be any other suitable data. The sensor data can be captured and provided by the apparatus, by the user device, a remote server system, by a set of secondary apparatuses, by an auxiliary sensor remote from the apparatus (e.g., external the apparatus), or by any other suitable computing system. The sensor data can be received by the user device at a predetermined frequency, received in response to the transmission event, received in real- or near-real time, received as the data is sent, or received at any other suitable frequency.

Receiving data from the apparatus S200 can additionally include connecting the user device to the apparatus. The user device can be wirelessly connected to the apparatus, connected to the apparatus by a wire, or otherwise connected to the apparatus. The user device is preferably removably or transiently connected to the apparatus. The user device is preferably connected to the apparatus in response to selection of a connection icon (e.g., in response to selection of an icon indicative of the apparatus), or be connected in response to the occurrence of any other suitable connection event. The user device can be simultaneously connected to a single apparatus or multiple apparatuses. In one variation, the user device can be connected to the apparatus via a Bluetooth or other short-range connection, wherein the apparatus can periodically or continuously broadcast a signal upon power-up, the user device can search for and display graphics indicative of apparatus physically proximal the user device (e.g., limited by the range of the short-range communication) upon selection of a search icon, and the user device can establish a transient connection to the apparatus in response to selection of the corresponding apparatus icon. However, the apparatus can connect to the user device in any suitable manner.

### 2.3 Processing the Programming Inputs into Control Instructions

Processing the programming inputs into control instructions based on the sensor data S300 functions to remotely generate control instructions for the apparatus, based on the programming inputs received from the user, that respond to the near-instantaneous apparatus operation conditions. Processing the sensor measurements into control instructions based on the programming inputs can additionally enable the apparatus to dynamically respond to unexpected environmental or operational conditions. Processing the sensor measurements into control instructions based on the programming inputs can additionally enable the apparatus to dynamically reflect (e.g., in real- or near-real time) the newly-entered programming input (e.g., perform the operations associated with the programming input).

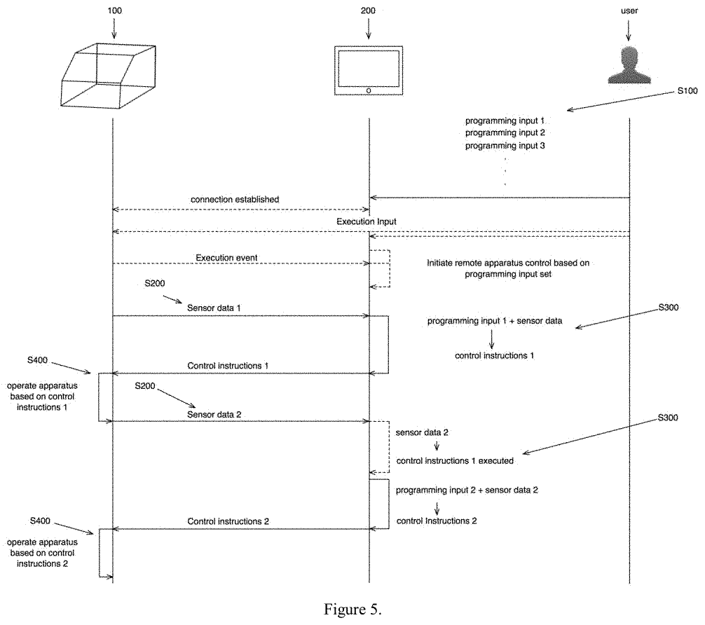

As shown in FIG. 5, the control instructions are preferably generated in response to receipt of a user input at the apparatus (e.g., button actuation at the apparatus, wherein data indicative of the button actuation can be sent to the user device to trigger control instruction generation), but can alternatively be generated in response to user device connection to the apparatus, in response to programming input receipt at the programming interface application, in response to a run command received at the programming interface application, or generated in response to the occurrence of any other suitable execution event. The control instructions are preferably entirely generated by the user device (e.g., by the programming interface application), but can alternatively be entirely or partially generated by the apparatus or a remote computing system. The control instructions are preferably sent to the apparatus, wherein the apparatus (more preferably, the apparatus processor but alternatively any other suitable component) receives the control instructions and operates according to the control instructions (e.g., wherein the processor or other control system controls the apparatus components to operate according to the control instructions). The control instructions are preferably sent as they are generated, but can alternatively be sent in bundles, sent in response to determination that the last control instruction was performed, or be sent at any other suitable frequency.

Each programming input of the set can be processed together with the remainder of the set, processed in subsets, or processed individually. The programming inputs are preferably processed automatically by the user device, apparatus, or other computing system, but can alternatively be processed in response to receipt of a user input, processed manually, or processed in any other suitable manner. The programming inputs can be processed into control instructions before the sensor data is received, after the sensor data is received, before the last set of control instructions is determined to have been performed, after the last set of control instructions is determined to have been performed, or be processed into control instructions at any other suitable time.

Processing the programming inputs S300 can include, at the user device: processing a first programming input into a first set of control instructions based on a first set of sensor data in response to receipt of the first set of sensor data; receiving a second set of sensor data; then processing the next programming input in the programming input sequence (e.g., the next unperformed programming input, second programming input, etc.) or subset thereof into a second set of control instructions based on the second set of sensor data (e.g., the subsequently received sensor data). However, the programming inputs can be otherwise processed. The method can additionally include iteratively repeating the method for successive sensor data sets and successive, unperformed programming inputs until the last programming input has been processed and performed. The first and second sets of sensor data can be recorded before the respective programming input is received at the programming interface application, recorded as the respective programming input is received at the programming interface application, or recorded after the respective programming input is received at the programming interface application. The control instructions can additionally or alternatively be generated based on the programming input and secondary data, wherein the secondary data can be user device sensor data, information received from a remote server, or be any other suitable data.

In one variation, as shown in FIG. 5, the control instructions are generated after the series of programming inputs have been received. This can function to execute entire programs on the apparatus. However, the control instructions can be generated (and sent) at any suitable time. The second set of sensor data is preferably recorded (by the apparatus or an external system) during apparatus operation according to the first set of control instructions, but can alternatively be recorded before or after apparatus operation according to the first set of control instructions. The second set of sensor data can be sent to the user device (e.g., from the apparatus or recording device) as the data is recorded, at a predetermined frequency, in response to a request received from the user device, or at any other suitable time.

As shown in FIG. 5, the method can additionally include determining apparatus performance (execution) of the first set of control instructions based on the second set of sensor data, wherein the next programming input is processed into the second set of control instructions in response to determination that the first set of control instructions have been performed. Performance of the control instruction set can be determined from the sensor data set by matching patterns, values, or other parameters of the sensor data with predetermined patterns, values, or other parameters associated with control instruction performance (e.g., based on the output of the specified apparatus capability or function, etc.) within a threshold degree of error (e.g., within 1% error). The second programming input can alternatively be processed based on a third set of sensor data, or be processed in any other suitable manner.

The method can additionally include dynamically modifying the set of programming inputs during programming input execution. This can function to permit the user to change the apparatus programming (e.g., the control path, conditional statements, etc.) on the fly. In this variation, the method can include receiving a programming input set modification as a programming input of the set is being executed, and generating a modified series of programming inputs in response to receipt of the modification. The method can additionally include automatically generating control instructions based on the subsequently received sensor data and the modified series of programming inputs. This can be performed irrespective of which programming input was modified or where the new programming input was inserted (e.g., wherein the apparatus performs the modified programming input after modification receipt) or be performed only if the modified or new programming input is after the instantaneous execution position within the programming input series. However, the programming input set can be otherwise modified, and apparatus control can be otherwise affected.

### 2.4 Controlling the Apparatus Based on the Control Instructions

Controlling the apparatus based on the control instructions S400 functions to remotely control the apparatus based on the programming inputs received at the user device. Controlling the apparatus can include, at the apparatus: receiving the control instructions at the apparatus and controlling apparatus sub-components to execute the control instructions. The control instructions can be received over the same communication channel as that used to send the sensor data, received over a different communication channel or protocol, or received in any other suitable manner. The control instructions can be executed (e.g., the apparatus operated based on the control instructions) in response to control instruction receipt, within a threshold time period of control instruction receipt (e.g., immediately, as soon as possible, within 5 seconds, etc.), in response to determination of a performance event (e.g., when a conditional event is met), or execute the control instructions at any other suitable time.

### 2.5 User Profile

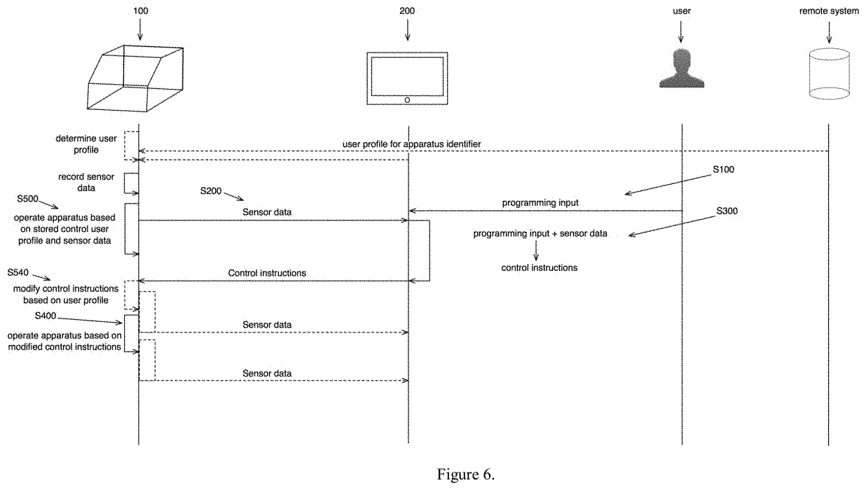

As shown in FIG. 6, the method can additionally include controlling an apparatus according to a user profile S500. The user profile can include a set of control instructions that control apparatus operation independent of user device control, and can define the default apparatus behavior. In one variation, the apparatus operates according to the user profile in a standby mode (e.g., when the apparatus is not receiving control instructions from the user device, being otherwise remotely controlled by the user device, or operating in a physical programming mode). In a second variation, the apparatus can entirely or partially operate according to the user profile during user device remote control, wherein the apparatus actions can be automatically supplemented or modified according to the user profile. However, the apparatus can operate in any suitable manner based on the user profile.

Controlling an apparatus according to a user profile S500 functions to execute application logic for directing apparatus actions. Controlling an apparatus according to a user profile can include controlling the apparatus in an autonomous mode and in a delegated control mode (e.g., the user device programming mode). The autonomous mode preferably engages a local control system. The local control system can be used independently from an application. The control instructions in an autonomous mode can be automatically generated based on at least a portion of a user profile stored on the apparatus. For example, when a user operates the apparatus without an open application, the user profile can be used directly to control apparatus action. A local version of the user profile preferably specifies various behavioral trigger-response patterns. A delegated control mode is preferably substantially similar to that described above, and can be engaged when an application is in communication with apparatus and executing control directives. The delegated mode can additionally or alternatively communicate with a remote control system accessible over the internet or any suitable network infrastructure.

The method can additionally include generating a user profile for the apparatus S520. The user profile can be automatically generated (e.g., based on patterns or associations with stored, historical apparatus actions and/or programming input sets), manually generated, predetermined, or otherwise determined.

In one variation, the history of programming input can impact the user profile configuration. The user profile configuration preferably reflects the combined “learning” of an apparatus, which is achieved through receiving programming input. As a user operates the apparatus, initializes programming instructions, designs customized instructions for the apparatus, the user profile can be updated to reflect the types of programming logic or patterns in programming logic. In this variation, determining the user profile can include storing a history of programming inputs associated with the apparatus, identifying a pattern of control instructions or programming inputs from the history of programming inputs, and generating the user profile based on the identified pattern.

The user profile can be generated by the user device, by a remote computing system, by the apparatus, or by any other suitable system. The user profile can be stored on the apparatus (e.g., wherein the user profile is sent to the apparatus if generated on a separate system), on the user device (e.g., wherein the user device can remotely control the apparatus, independent of programming inputs), on a remote computing system (e.g., wherein the user profile is retrieved by the apparatus or user device), or on any other suitable computing system.

The user profile can additionally be gradually modified (updated) to reflect the way a user typically programs the apparatus to operate. Additionally, user profile configuration can define actions to particular types of event triggers. For example, if a user typically requires a notification signal during a particular event, that notification signal can be used as a default for that event. When a new program feedback is received, the program feedback can process the current program; identify any patterns, and calculate user profile control instructions as a function of the new program feedback and past control instructions.

The user profile configuration update preferably occurs across all applications, but user profile updating can be disabled for select applications. Each user account is preferably associated with a single user profile for a given apparatus identified by an apparatus identifier (globally unique or non-unique identifier), but can alternatively be associated with multiple user profiles for the apparatus. In the latter variation, the user profile instantaneously assigned to the apparatus can be manually selected by the user, automatically selected (e.g., based on time of day, estimated frequency, etc.), or selected in any other suitable manner. Each apparatus can support (e.g., store) one or more user profiles. In one implementation, multiple users can use an apparatus where one user logs in and become the active user of an apparatus at any particular time. User profile can be scoped by apparatus, by user, by application, by set of applications, or by any suitable scope. User profiles can additionally be saved, shared, forked, or modified in any suitable manner. Additionally, a user account or apparatus can have a set of different user profiles that can be selectively activated or used in aggregate. In one implementation, there is a global user profile configuration for an account, but a secondary application specific user profile that augments the global configuration only when using that particular application. Similarly, a new user profile can be formed through combination of other user profiles. For example, a default user profile configuration of an apparatus can be used when there is no specific active user, wherein the default user profile configuration is a combination of user profile configurations from multiple users of the apparatus.

The method can additionally include supplementing or modifying the control instructions based on the user profile S540, wherein the control instructions are generated based on the programming input (example shown in FIG. 6). The control instructions can be supplemented or modified by the apparatus, by the user device, or by any other suitable computing system. The user profile preferably works in cooperation with programming input of an application to update how the apparatus responds to the environment. While programming input is preferably dependent on the currently loaded and possibly the particular application controlling the apparatus, the user profile configuration can be expressed independent of the application and is more dependent on the progressive development of the apparatus. The programming input preferably specifies high priority control instructions, which preferably receives higher-level priority than user profile configuration-based control instructions. The user profile configuration can be used as a default customized behavior when explicit control instructions are not supplied by a program or other higher priority control instructions (e.g., safety control instructions). For example, if the user profile specifies that red light should be displayed whenever the ambient temperature exceeds a given value, the apparatus can be controlled to display the red light when the control instruction specifies the apparatus operate at a temperature above the threshold temperature, even though the control instructions do not specify a display color.

In one variation, the control instructions can be modified based on the user profile, wherein the output manipulated by the control instructions can be entirely or partially influenced by the user profile instructions. In this variation, the method can include identifying the control instructions as one of a set (e.g., wherein the set is associated with an apparatus sub-component, wherein the set specifies control instructions that can be modified, etc.) and modifying the control instructions in a predetermined manner, based on the user profile. However, the control instructions can be otherwise modified or supplemented.

The method can additionally include updating the programming inputs in real-time. Programming input can be automatically pushed to the apparatus. The apparatus can be impacted as a program is edited and/or created. Alerts and warnings can be expressed in the user interface as well as in the operation of the apparatus. In some cases, for example, the user profile configuration can alter how the apparatus expresses a warning or notification.

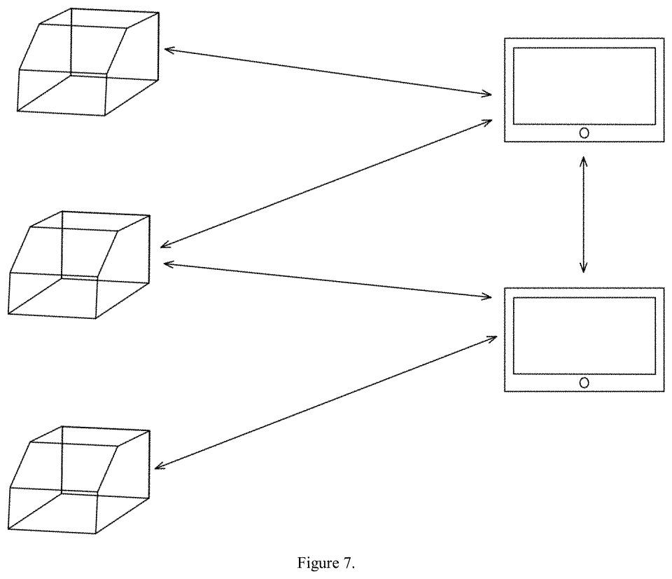

Additionally, while the method is described for a one-to-one relationship of applications and apparatuses, the method and system can additionally support many apparatuses to one controller scenarios, one apparatus to multiple controllers scenarios, and many apparatuses controlled by many controllers as shown in FIG. 7. Multiple, users can collaborate (or compete) in setting programming input for one apparatus. Similarly, programming input can be transmitted to multiple apparatuses.

The system and method can be embodied and/or implemented at least in part as a machine configured to receive a computer-readable medium storing computer-readable instructions. The instructions are preferably executed by computer-executable components preferably integrated with the apparatus system and programming interface application. The computer-readable medium can be stored on any suitable computer-readable media such as RAMs, ROMs, flash memory, EEPROMs, optical devices (CD or DVD), hard drives, floppy drives, or any suitable device. The computer-executable component is preferably a general or application specific processor, but any suitable dedicated hardware or hardware/firmware combination device can alternatively or additionally execute the instructions.

As a person skilled in the art will recognize from the previous detailed description and from the figures and claims, modifications and changes can be made to the preferred embodiments of the invention without departing from the scope of this invention defined in the following claims.

What is claimed:

1. An iterative computer-implemented method and laboratory apparatus for calibrating and controlling the temperature within said apparatus, the apparatus including a set of sensors and a processor configured to control apparatus operation using a user device, the method comprising the steps of:
a. Receiving a series of programming inputs from a user at the user device;
b. Receiving a set of sensor measurements from the apparatus;
c. Automatically generating a set of control instructions based on the set of sensor measurements and unperformed programming input of the series;
d. Sending the set of control instructions to the apparatus, wherein the apparatus is operated based on the set of control instructions;
e. Iteratively repeating b. to d. for successive programming inputs based on subsequent sets of sensor measurements received from the apparatus, wherein the subsequent sets of sensor measurements are recorded during apparatus operation based on a previous set of control instructions and monitoring apparatus performance of the previous set of control instructions based on the subsequent set of sensor measurements received from the apparatus, comprising:
i. Iteratively repeating b. to d. for the successive programming input in response to the apparatus performing the previous set of control instructions within a threshold degree of error;

2. The method of claim 1, wherein the programming inputs are received at a programming interface application on the user device, wherein the programming interface application comprises a visual programming interface.

3. The method of claim 2, wherein the programming inputs comprise programming components.

4. The method of claim 2, wherein the set of control instructions is automatically generated in response to receipt of a new programming input from the user, wherein the set of sensor measurements is received after the new programming input is received, and the set of control instructions is generated based on the new programming input and the set of sensor measurements.

5. The method of claim 1, further comprising, at the user device: determining performance of the previous set of control instructions by the apparatus based on the set of sensor measurements received from the apparatus after sending the set of control instructions to the apparatus.

6. An iterative computer-implemented method and laboratory apparatus for calibrating and controlling the ambient temperature within said apparatus, the apparatus including a set of sensors and a processor configured to control apparatus operation using a user device, the method comprising, at the user device, remote from the apparatus:
a. Receiving a series of programming inputs from a user at a programming interface application on the user device;
b. Received a set of sensor measurements from the apparatus;
c. Automatically generating a set of control instructions for the apparatus based on a programming input of the series and the set of sensor measurements;
d. Sending the set of control instructions to the apparatus; at the apparatus:
i. Receiving the set of control instructions from the user device;
ii. Operating the apparatus based on the set of control instructions, wherein the apparatus is operated based on the first set of control instructions within a threshold time period after first set of control instruction receipt at the apparatus;
iii. Recording a second set of sensor measurements during the apparatus operation;
iv. Sending the second set of sensor measurements to the user device; at the user device:
v. Determining execution of the set of control instructions by the apparatus based on data received from the apparatus;
vi. Automatically generating a second set of control instructions for the apparatus based on a succeeding programming input of the series and the second set of sensor measurements;
vii. Sending the second set of control instructions to the apparatus; and
viii. Operating the apparatus according to the second set of control instructions, wherein the apparatus is operated based on the second set of control instructions within the threshold time period after second set of control instruction receipt at the apparatus.

7. The method of claim 1, wherein the subsequent set of sensor measurements are received by the user device as a near-real time sensor measurement stream from the apparatus.

8. The method of claim 6, wherein determining execution of the programming input by the apparatus based on data received from the apparatus comprises determining execution of the programming input based on the second set of sensor measurements.

9. The method of claim 6, wherein the set of control instructions is automatically generated in response to receipt of a user input at the apparatus.

10. The method of claim 6, wherein sending the second set of sensor measurements comprises streaming the sensor measurements from the apparatus to the user device in near-real time.

11. The method of claim 6, wherein the programming inputs comprise conditional apparatus actions, the method further comprising:
a. Sending the programming inputs to the apparatus;
b. Storing the programming inputs at the apparatus as a user profile; and at the apparatus
c. Automatically operating the apparatus based on the user profile.

12. The method of claim 11, wherein i. to viii. is performed in response to the apparatus wirelessly or through wired communication connecting to the user device, wherein the apparatus is automatically operated based on the user profile independent of user device connection.

13. The method of claim 11, further comprising:
a. Receiving a second series of programming inputs at a user device;
b. Receiving a third set of sensor measurements from the apparatus at the user device;
c. Generating a third set of control instructions based on the sensor measurements at the user device;
d. Sending the third set of control instructions to the apparatus from the user device;
e. Receiving the third set of control instructions at the apparatus;
f. Modifying the third set of control instructions into modified control instructions based on the user profile; and
g. Operating the apparatus based on the modified control instructions.

14. A method for laboratory apparatus operation, using a user device, to calibrate and control the ambient temperature within said apparatus through apparatus feedback, the apparatus including a set of sensors and a processor configured to control apparatus operation using a user device, the method comprising, at the apparatus:
a. Automatically operating the apparatus in a standby mode, comprising:
i. Recording a set of sensor measurements;
ii. Operating based on stored control instructions and the set of sensor measurements;
b. In response to wireless or wired connection with a user device:
i. Recording a second set of sensor measurements;
ii. Transmitting the second set of sensor measurements to the user device;
iii. Receiving a set of control instructions from the user device, the set of control instructions automatically generated by the user device based on the second set of sensor measurements and a programming component stored by the user device;
iv. Modifying a control instruction of the received set of instructions based on the stored control instructions;
v. Automatically executing the modified set of control instructions;
vi. Recording a third set of sensor measurements during control instruction execution;
c. At the user device:
i. Storing a history of programming components associated with the apparatus;
ii. Identifying a pattern of conditional control instructions from the history of programming components;
iii. Generating updated control instructions for the apparatus based on the identified pattern; and
iv. Sending the updated control instructions to the apparatus;
d. At the apparatus:
i. Receiving and storing the updated control instructions; and
ii. Operating based on the updated control instructions.

15. The method of claim 14, further comprising, at the apparatus:
a. Recording a third set of sensor measurements;
b. Transmitting the third set of sensor measurements to the user device;
c. Receiving a third set of control instructions from the user device, the third set of control instructions automatically generated by the user device based on the second set of sensor measurements and a programming component stored by the user device; and
d. Automatically executing the third set of control instructions.

16. The method of claim 15, further comprising, at the user device:
a. Receiving a series of programming inputs, wherein the third set of control instructions are generated based on an unperformed programming input of the series;
b. Verifying execution of the third set of control instructions by the apparatus based on a fourth set of sensor measurements received from the apparatus;
c. Automatically generating a fourth set of control instructions for the apparatus based on a succeeding programming input of the series and fourth set of sensor measurements; and
d. Sending the fourth set of control instructions to the apparatus for execution.
